(19) United States
(12) Patent Application Publication
(10) Pub. No.: US 2006/0197605 A1
(43) Pub. Date: Sep. 7, 2006

(54) Broadband modulation pli, and modulation factor adjusting method therefor

(76) Inventors: Shunsuke Hirano, Yokohama-shi (JP); Taketoshi Ochi, Yokosuka-shi (JP)

Correspondence Address: PEARNE & GORDON LLP, 1801 EAST 9TH SRTEET, SUITE 1200, CLEVELAND, OH, 44114-3108, US

(21) Appl. No.: 10/568,318

(22) PCT Filed: Jul. 21, 2004
(86) PCT No.: PCT/JP04/10679

§ 371 Date: Feb. 15, 2006

(30) Foreign Application Priority Data
Aug. 22, 2003 (JP) 2003-298857

(51) Int. Cl. H03L 7/00

(52) U.S. Cl. 331/16

(57) ABSTRACT

A problem of the invention is to provide a wide band modulation PLL having an excellent modulation accuracy at low cost.

With respect to a PLL portion including VCO (21), a divider (22), a phase comparator (23), and a loop filter (24), a dividing ratio of the divider (24) is modulated by a dividing ratio generating portion (29) by controlling a control voltage of VCO (21) by a control signal generating portion (30). VCO (21) includes two control terminals, and the control signal generating portion (30) inputs the control signal to one of the control terminals. In controlling a modulation degree, the dividing ratio generating portion (29) is inputted with a calibration data f_{c1} and the control signal generating portion (30) is inputted with a calibration data f_{c2}. A demodulator (31) demodulates output signals of VCO (21) when the respective calibration data are inputted and modulation degree controlling means (32) outputs a modulation degree control signal to the control signal generating portion (30) based on the demodulated signals.

### TECHNICAL FIELD

The present invention relates to a wide band modulation PLL capable of generating and outputting an RF (Radio Frequency) modulation signal modulated by a modulation signal having a band width wider than a band width of PLL and a method of controlling a modulation degree thereof.

### BACKGROUND ART

Generally, low cost, lower power consumption, excellent noise characteristic and modulation accuracy are requested for a PLL (Phase Locked Loop) modulating circuit. When modulated by PLL, it is preferable to make a frequency band (PLL band) width wider than a frequency band (modulation band) of a modulation signal to improve modulation accuracy.

However, when the PLL band width is widened, a noise characteristic is deteriorated, hence, there has been devised a technology referred to as two points modulation in which a PLL band width is set to be narrower than a modulation band width and modulation in PLL band and modulation outside of the PLL band are applied at two portions different from each other (refer to, for example, Patent Reference 1).

FIG. 8 is an outline constitution diagram showing a wide band modulation PLL of a background art. As shown by FIG. 8, the wide band modulation PLL of the background art is provided with a voltage control oscillator (hereinafter, VCO) 1 in which an oscillation frequency is changed in accordance with a voltage of a control voltage terminal (Vt), a divider 2 for dividing a frequency of an RF modulation signal outputted from VCO1, a phase comparator 3 for comparing phases of an output signal of the divider 2 and a reference signal and outputting a signal in accordance with a phase difference thereof, a modulation sensitivity table 7 for outputting a modulation signal to PLL including a loop filter 4 for averaging an output signal of the phase comparator based on modulation data, a D/A converter 10 for converting an output signal of the modulation sensitivity table 7 into an analog voltage while controlling a gain in accordance with a gain control signal from a control portion 6, a delta sigma modulator 9 for subjecting a signal constituted by adding channel selecting information to the output signal from the modulation sensitivity table 7 to output to the divider 2 as a dividing ratio, and an A/D converter 11 for converting a voltage value of Vt into a digital value to output to the control portion 6.

FIG. 9 is a diagram showing a frequency characteristic for explaining operation of a wide band modulation PLL. Here, a transfer function of PLL is designated by notation H(s) (where s=jω) . H(s) is provided with a low pass characteristic as shown by FIG. 9. A modulation signal added to a dividing ratio set to the divider 2 is subjected to a low pass filter of the transfer function H(s). On the other hand, a modulation signal applied to the control voltage terminal (Vt) of VCO1 is applied with a high pass filter of a transfer function 1-H(s) as shown by FIG. 9.

The two modulation components are added at the control voltage terminal of VCO1 and therefore, the modulation signal is applied with a flat characteristic indicated by a broken line of FIG. 9 equivalently to apply to VCO1. As a result, an RF modulation signal having a wide band covering also outside of the PLL band can be outputted.

Meanwhile, an amplitude of the modulation signal inputted to the control voltage terminal of VCO1 is converted into a deviation in a frequency of the RF modulation signal outputted from VCO1. A conversion gain thereof is referred to as conversion sensitivity and a unit thereof is generally [Hz/V].

An amplitude of a signal outputted from the D/A converter 10 needs to match with the modulation sensitivity of VCO1. Because when the amplitude and the modulation sensitivity are not matched, a transfer function 1-H(s) is multiplied by a deviation amount (a times in this case) as shown by FIG. 10, a characteristic thereof synthesized with H(s) indicated by the broken line does not become flat with respect to the frequency. This constitutes a factor of deteriorating a modulation accuracy.

FIG. 11 is a diagram showing an example of a general characteristic representing a change in an output signal frequency with respect to a control voltage of VCO. The modulation sensitivity is represented by an inclination of a curve of the voltage-frequency characteristic. As shown by FIG. 11, the modulation sensitivity differs by the oscillation frequency of VCO and therefore, in order to provide the same frequency deviated modulation signal by a different oscillation frequency of VCO, it is necessary to change the amplitude of the modulation signal inputted to the control voltage terminal of VCO in accordance with the oscillation frequency of VCO.

FIG. 12 is a diagram showing a general characteristic of the modulation sensitivity with respect to the oscillation frequency of VCO. It is known from the drawing that the modulation sensitivity is changed by the oscillation frequency.

An explanation will be given here of an example when it is necessary to change a control voltage by being caused by that the modulation sensitivity differs by the oscillation frequency of VCO. Assume that a modulation sensitivity at a frequency of 2 GHz of VCO1 is 100 MHz/V and a maximum frequency deviation of a modulation signal is 5 MHz. In this case, it is necessary to input a signal having a maximum amplitude of 500 mV to Vt. Meanwhile, assume that the modulation sensitivity becomes 80 MHz/V when the frequency of VCO1 is 2.1 GHz. In this case, it is necessary to input a signal having a maximum amplitude of 62.5 mV to Vt. That is, it is necessary to change an output signal amplitude of the D/A converter 10 by the frequency of VCO1.

Further, a modulation sensitivity with respect to a modulation component included in a dividing ration set to the divider 2 becomes that of the frequency of the reference signal and remains unchanged with respect to a frequency of VCO1. For example, an explanation will be given by taking an example of a case in which it is assumed that a frequency of VCO1 is 2 GHz, the frequency of the reference signal is 1 MHz, and the maximum frequency deviation of the modulation signal is 5 MHz. In this case, a maximum change width of the dividing ratio becomes 5. Therefore, the frequency of VCO1 is irrelevant to the calculation.

In the case of FIG. 8, a characteristic of the modulation sensitivity with respect to a frequency is provided as the modulation sensitivity table 7, when the channel frequency is changed, the modulation sensitivity is connected by calculating an amount of a variation in the control voltage to control a gain of the D/A converter.

Here, FIG. 13 shows an example of a principle diagram of VCO. VCO1 is constituted by an inductor L, a capacitor C, a variable capacitance diode Cᵥ, a capacitance of which is changed by a voltage value of the control voltage Vt, and an active element 100, and the oscillation frequency f_{vco} is determined by Equation (1).
f_{vco}=½π\sqrt{L(C+Cυ)} (1)

When such VCO is integrated to LSI, values of elements of the inductor L, the capacitor C, the variable capacitance diode Cᵥ and the like are changed by a dispersion in fabrication. Thereby, the characteristic of the modulation sensitivity with respect to the oscillation frequency of VCO differs by respectives of LSI.

However, according to the wide band modulation PLL of the background art, it is necessary to prepare the modulation sensitivity table for the characteristic of the modulation sensitivity of each LSI caused by the variations. That is, it is necessary to measure individually a table of the modulation sensitivity with respect to the frequency for each LSI, and write to hold the table to a memory or the like.

In order to prepare the modulation sensitivity table, it is necessary to measure the modulation sensitivities with respect to frequencies of all the channels used and the frequency of PLL is switched by a number of measured points. Therefore, there is brought about a situation in which not only much time is taken and fabrication cost is increased but also a memory mount is large and cost of LSI is increased.

(Patent Reference 1) U.S. Pat. No. 6,211,747

### DISCLOSURE OF THE INVENTION

The invention has been carried out in order to resolve the problem of the background art and it is an object thereof to provide a wide band modulation PLL having an excellent modulation accuracy at low cost.

According to the invention, there is provided a wide band modulation PLL comprising a PLL portion including a voltage control oscillator, a divider for dividing an output signal of the voltage control oscillator, a phase comparator connected to a post stage of the divider, and a loop filter for averaging an output of the phase comparator, a first modulation input portion for inputting a first modulation signal to the voltage control oscillator to modulate based on an inputted modulation data, and a second modulation input portion for inputting a second modulation signal to a position of the PLL portion different from the voltage control oscillator based on the modulation data, wherein the voltage control oscillator includes a first control terminal inputted with the first modulation signal and a second control terminal inputted with a signal based on the second modulation signal.

By the constitution, the wide band modulation PLL having an excellent modulation accuracy can simply be provided.

Further, according to the wide band modulation PLL of the invention, the first modulation input portion and the second modulation input portion are respectively inputted with a first calibration data and a second calibration data in controlling a modulation degree, and the modulation degree of the first modulation input portion is controlled by comparing signals based on outputs from the voltage control oscillator when the first calibration data and the second calibration data are inputted.

By the constitution, the wide band modulation PLL which is small-sized and is provided with an excellent modulation accuracy can be provided at low cost, further, it is not necessary to execute calibration while changing a frequency of VCO and therefore, the calibration can be finished in a short period of time.

Further, according to the wide band modulation PLL of the invention, the first calibration data is a sine wave signal outside of a PLL band and the second calibration data is a sine wave signal in the PLL band.

By the constitution, there can be prevented a deterioration in a modulation accuracy caused by a difference between gains by two points modulation when modulation is executed over a wide band of inside of a PLL band and outside of the PLL band.

Further, according to the wide band modulation PLL of the invention, maximum frequency deviations of the first calibration data and the second calibration data are equal to each other.

Further, according to the wide band modulation PLL of the invention, the modulation degree of the first modulation input portion is controlled based on a difference between the maximum frequency deviations of the signals based on outputs of the voltage control oscillator when the first calibration data is inputted and when the second calibration data is inputted.

By the constitution, the modulation degree can simply be controlled.

Further, according to the wide band modulation PLL of the invention, the second modulation portion includes dividing ratio generating means for controlling a dividing ratio of the divider based on a carrier frequency data and the modulation data.

By the constitution, when two points of the dividing ratio and the voltage control oscillator are modulated, the wide band modulation PLL which is small-sized and is provided with an excellent modulation accuracy can be provided at low cost, further, it is not necessary to execute calibration while changing the frequency of VCO and therefore, the calibration can be finished in a short period of time.

Further, according to the wide band modulation PLL of the invention, the second modulation portion includes a direct digital synthesizer for generating a modulation signal based on a carrier frequency data and the modulation data to output to the phase comparator.

By the constitution, the wide band modulation PLL which is small-sized and is provided with an excellent modulation accuracy can be provided at low cost, further, it is not necessary to execute calibration while changing the frequency of VCO and therefore, the calibration can be finished in a short period of time.

Further, according to the wide band modulation PLL of the invention, the divider includes a plurality of dividers having fixed dividing ratios which are consecutively connected.

By the constitution, the wide band modulation PLL which is small-sized and is provided with an excellent modulation accuracy can be provided at low cost and with small power consumption.

Further, the invention provides a wireless terminal apparatus comprising the wide band modulation PLL.

By the constitution, an excellent modulation accuracy can be provided inexpensively.

According to the invention, there is provided a modulation degree control system of a wide band modulation PLL comprising the wide band modulation PLL, a demodulator for demodulating an output of the voltage control oscillator of the wide band modulation PLL, and modulation degree controlling means for outputting a modulation degree control signal to the first modulation input portion of the wide band modulation PLL by controlling a modulation degree based on an output of the demodulator.

By the constitution, the wide band modulation PLL which is small-sized and is provided with an excellent modulation accuracy can be provided at low cost, further, it is not necessary to execute calibration while changing the frequency of VCO and therefore, the calibration can be finished in a short period of time.

According to the invention, there is provided a polar modulation system comprising the wide band modulation PLL, an envelope signal generating portion for generating an envelope signal based on an inputted amplitude modulation data, and a polar demodulator for generating a transmitting output signal based on an output of the voltage control oscillator of the wide band modulation PLL and an output signal of the envelope signal generating portion.

By the constitution, the wide band modulation PLL which is small-sized and is provided with an excellent modulation accuracy can be provided at low cost, further, it is not necessary to execute calibration while changing the frequency of VCO and therefore, the calibration can be finished in a short period of time.

According to the invention, there is provided a modulation degree control system of a polar modulation system comprising the polar modulation system, a demodulator for demodulating an output of the voltage control oscillator of the wide band modulation PLL, and modulation degree controlling means for outputting a modulation degree control signal to the first modulation input portion of the wide band modulation PLL by controlling a modulation degree based on an output of the demodulator.

By the constitution, the wide band modulation PLL which is small-sized and is provided with an excellent modulation accuracy can be provided at low cost, further, it is not necessary to execute calibration while changing the frequency of VCO and therefore, the calibration can be finished in a short period of time.

According to the invention, there is provided a method of adjusting a modulation degree of a wide band PLL which is a method of controlling a modulation degree of a wide band modulation PLL comprising a PLL portion including a voltage control oscillator, a divider for dividing an output signal of the voltage control oscillator, a phase comparator connected to a post stage of the divider, and a loop filter for averaging an output of the phase comparator, the method comprising a step of inputting a first calibration data to a first control terminal of the voltage control oscillator, a step of inputting a second calibration data to a position of the PLL portion different from the voltage control oscillator, a step of demodulating the output of the voltage control oscillator when the first calibration data is inputted, a step of demodulating an output of the voltage control oscillator when the second calibration data is inputted, and a step of controlling a modulation degree of a modulation signal inputted to the first control terminal of the voltage control oscillator based on the demodulated signal.

By the method, the wide band modulation PLL which is small-sized and is provided with an excellent modulation accuracy can be provided at low cost, further, it is not necessary to execute calibration while changing the frequency of VCO and therefore, the calibration can be finished in a short period of time.

Further, according to the invention, there is provided a method of controlling a modulation degree of a wide band modulation PLL which is a method of controlling a modulation degree of a polar modulation system comprising a wide band modulation PLL including a voltage control oscillator, a divider for dividing an output signal of the voltage control oscillator, a phase comparator connected to a post stage of the divider, and a loop filter for averaging an output of the phase comparator, the method comprising a step of inputting a first modulation signal based on a first calibration data to a first control terminal of the voltage control oscillator, a step of inputting a second modulation signal based on a second calibration data to a position of the PLL portion different from the voltage control oscillator, a step of synthesizing an output signal of the voltage control oscillator of the PLL portion based on an amplitude modulation data at a polar modulator, a step of demodulating an output of the polar modulator when the first calibration data is inputted, a step of demodulating the output of the polar modulator when the second calibration data is inputted, and a step of controlling a modulation degree of a modulation signal inputted to the first control terminal of the voltage control oscillator based on the demodulated signal.

By the method, the wide band modulation PLL which is small-sized and is provided with an excellent modulation accuracy can be provided at low cost, further, it is not necessary to execute calibration while changing a frequency of VCO and therefore, the calibration can be finished in a short period of time.

According to the invention, the wide band modulation PLL having the excellent modulation accuracy can be provided at low cost.

### BRIEF DESCRIPTION OF THE DRAWINGS

FIG. 1 is an outline constitution diagram showing a wide band modulation PLL for explaining a first embodiment.

FIG. 2 is a principle diagram of VCO of the wide band modulation PLL according to the first embodiment.

FIG. 3 is an outline constitution diagram showing an example of a control signal generating portion of the wide band modulation PLL according to the first embodiment.

FIG. 4 is an outline constitution diagram showing an example of a dividing ratio generating portion of the wide band modulation PLL according to the first embodiment.

FIG. 5 is a diagram showing an output waveform of a demodulator of the wide band modulation PLL according to the first embodiment.

FIG. 6 is an outline constitution diagram showing a wide band modulation PLL for explaining a second embodiment of the invention.

FIG. 7 is an outline constitution diagram showing a polar modulation system for explaining a third embodiment of the invention.

FIG. 8 is an outline constitution diagram showing a wide band modulation PLL of a background art.

FIG. 9 is a diagram showing a frequency characteristic for explaining operation of a wide band modulation PLL.

FIG. 10 is a diagram showing a frequency characteristic for explaining operation of a wide band modulation PLL.

FIG. 11 is a diagram showing an example of a general characteristic representing a change in an output frequency with respect to a control voltage of VCO.

FIG. 12 is a diagram showing a general characteristic of a modulation sensitivity with respect to an oscillation frequency of VCO.

FIG. 13 shows an example of a principle diagram of VCO.

Further, in the drawings, notations 21, 50 designate voltage control oscillators, notation 22 designates a divider, notation 23 designates a phase comparator, notation 24 designates a loop filter, notation 25 designates a modulation signal generating portion, notation 26 designates a calibration data generating portion, notations 27, 28 designate selectors, notation 29 designates a dividing ratio generating portion, notation 30 designates modulation degree controlling means, notation 31 designates a demodulator, notation 32 designates modulation degree controlling means, notation 33 designates an envelop signal generating portion, notation 34 designates a polar demodulator, notation 35 designates DDS, notations 200, 300 designate differentiators, notations 201, 301 designate amplifiers, notation 202 designates a variable gain amplifier, notation 203 designates a D/A converter, notation 302 designates an adder, and notation 303 designates a delta sigma modulator.

### BEST MODE FOR CARRYING OUT THE INVENTION

### First Embodiment

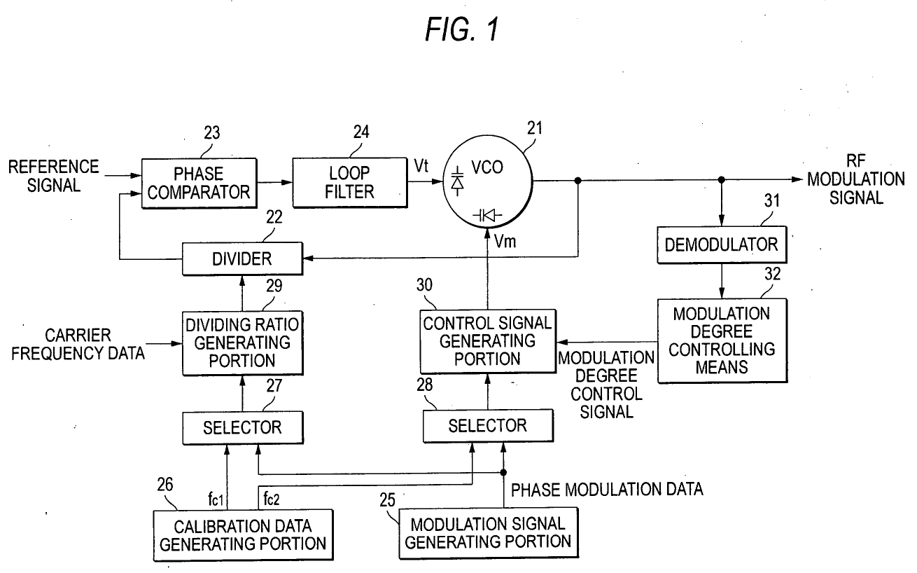

FIG. 1 is an outline constitution diagram showing a wide band modulation PLL for explaining a first embodiment. In FIG. 1, the wide band modulation PLL according to the first embodiment is provided with a PLL portion including the voltage control oscillator (hereinafter, VCO) 21 which includes two control voltage terminals for PLL (input voltage Vₜ) and for inputting a modulation signal (input voltage Vₘ) and in which an oscillation frequency is changed in accordance with the respective input voltages, the divider 22 for dividing an output signal of VCO 21, the phase comparator 23 for comparing a phase of a reference signal and a phase of an output signal of the divider 22 and outputting a signal in accordance with a phase difference thereof, and the loop filter 24 for outputting a control voltage Vₜ by smoothing an output signal of the phase comparator 23.

Further, the wide band modulation PLL according to the first embodiment is provided with the modulation signal generating portion 25 for generating a phase modulation data, the calibration data generating portion 26 for generating a data for calibration, the selectors 27, 28 for selecting either one of the inputted data for calibration and the inputted phase modulation data, the dividing ratio generating portion 29 for generating a dividing ratio by synthesizing an output signal of the selector 27 and a carrier frequency data, the control signal generating portion 30 for generating and outputting the control voltage Vₘ of VCO 21 based on an output signal of the selector 28 and a modulation degree control signal, the demodulator 31 for demodulating an RF modulation signal outputted by VCO 21, and the modulation degree controlling means 32 for generating the modulation degree control signal based on an output of the demodulator 31 to output to the control signal generating portion 30.

Here, the calibration data generating portion 26 outputs two kinds of calibration data f_{c1}, f_{c2}. In FIG. 1, the calibration data f_{c1} is inputted to the selector 27 and the calibration data f_{c2} is inputted to the selector 28, respectively.

Here, the carrier frequency data and the reference signal are outputted from a control portion, not illustrated. Further, the data and the signal may be outputted by individual control portions, or may be outputted by a single control portion for controlling the wide band modulation PLL. Further, when the wide band modulation PLL is applied to a wireless communication apparatus or the like of a mobile terminal apparatus, a wireless base station or the like, the control signal and the data may be outputted by a control portion for controlling operation of such a wireless communication apparatus or the like.

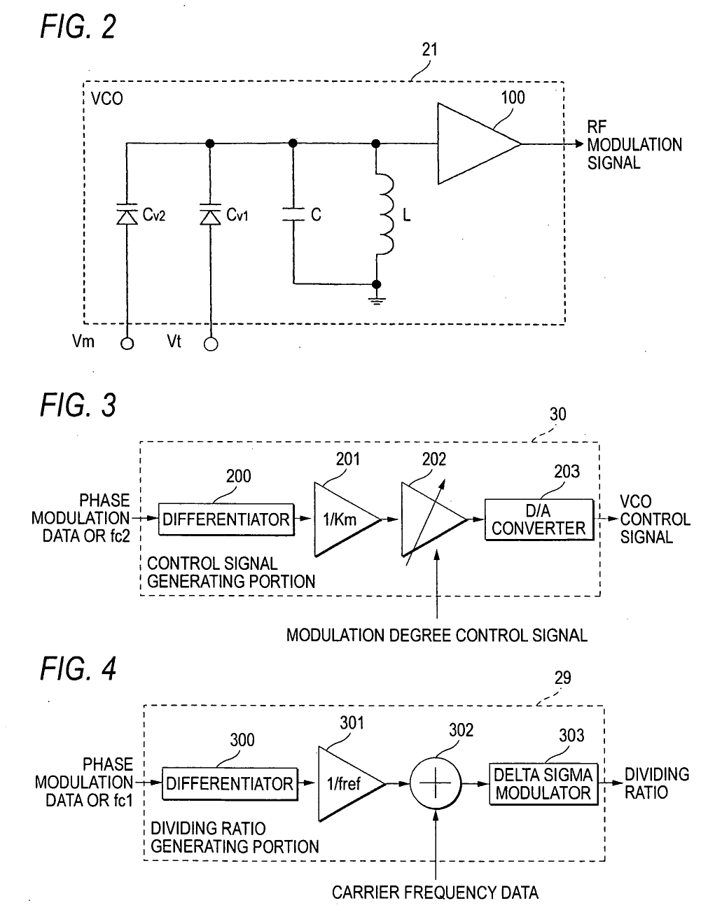

FIG. 2 is a principle diagram of VCO of the wide band modulation PLL according to the first embodiment. VCO 21 is provided with an inductor L, a capacitor C, a variable capacitance diode Cᵥ₁, a variable capacitance diode Cᵥ₂ and an active element 100 and an oscillation frequency f_{vco} is determined by Equation (2).
f_{vco}− 1/2π\sqrt{L(C+C_{υ1}+C_{υ2})} (2)

Here, according to the embodiment, the frequency of VCO 21 is controlled by changing a capacitance value Cᵥ₁ by controlling the voltage Vₜ. Thereby, a bias potential of Vₘ can be fixed without depending on the frequency of VCO 21 and therefore, the modulation sensitivity of VCO 21 by a change in Vₜ can be made substantially constant.

Next, the control signal generating portion 30 will be explained in reference to FIG. 3. FIG. 3 is an outline constitution diagram showing the control signal generating portion of the wide band modulation PLL according to the first embodiment. As shown by FIG. 3, the control signal generating portion 30 is provided with the differentiator 200, the amplifier 201, the variable gain amplifier 202, and the D/A converter 203 for generating the control signal to VCO 21.

The phase modulation data outputted from the modulation signal generating portion 25 or the calibration data f_{c2} outputted from the calibration data generating portion 26 is inputted to the amplifier 201 via the differentiator 200. Here, a gain of the amplifier 201 is 1/Kₘ and notation Kₘ designates the modulation sensitivity of VCO 21 with respect to the control voltage Vₘ. By the amplifier 201, the phase modulation data or the calibration data f_{c2} is converted into a dimension of a voltage.

An output signal of the amplifier 201 is inputted to the variable gain amplifier 202 the gain of which is controlled based on the modulation degree control signal outputted from the modulation degree controlling means 32. An output signal of the variable gain amplifier 202 is converted into an analog signal by the D/A converter 203 and is outputted as the control signal of VCO 21. Further, when a frequency is intended to modulate by PLL, the differentiator 200 may be deleted. Further, a position of the D/A converter may not necessarily be disposed at the position. A boundary of digital and analog may be disposed at anywhere.

FIG. 4 is an outline constitution diagram showing an example of the dividing ratio generating portion of the wide band modulation PLL according to the first embodiment. As shown by FIG. 4, the dividing ratio generating portion 29 is provided with the differentiator 300, the amplifier 301, the adder 302 and the delta sigma modulator 303 for generating the dividing ratio for the divider 22.

The phase modulation data outputted from the modulation signal generating portion 25 or the calibration data f_{c1} outputted from the calibration data generating portion 26 is inputted to the amplifier 301 via the differentiator 300. Here, a gain of the amplifier 301 is 1/f_{ref} and notation f_{ref} designates a frequency of the reference signal. The phase modulation data or the calibration data is converted into a dimension of the dividing ratio by the amplifier 301.

An output signal of the amplifier 301 is added with a carrier frequency data at the adder 302 and thereafter inputted to the delta sigma modulator 303. The delta sigma modulator 303 subjects an output signal of the adder 302 to delta sigma modulation to output as the dividing ratio of the divider 22. Further, when a frequency is intended to modulate by PLL, the differentiator 300 may be deleted.

Next, an explanation will be given of a method of adjusting a modulation degree in the wide band modulation PLL according to the embodiment. First, the dividing ratio generating portion 29 generates a dividing ratio in accordance with only a carrier frequency data to lock the PLL portion to a frequency in accordance with the carrier frequency data. When the PLL portion is locked to the frequency in accordance with the carrier frequency data, the calibration data generating portion 26 outputs a sine wave of the frequency f_{c1} (refer to FIG. 10) in the PLL band as data for calibration.

The calibration data f_{c1} outputted by the calibration data generating portion 26 is inputted to the dividing ratio generating portion 29 via the selector 27 and the dividing ratio generating portion 29 generates a dividing ratio and modulates the dividing ratio. Thereby, VCO 21 outputs an RF modulation signal modulated by the frequency of f_{c1}.

The demodulator 31 demodulates the output signal of VCO 21 and outputs a sine wave having the frequency of f_{c1}. Further, the modulation degree coontrolling means 32 reads an amplitude value of the sine wave to hold.

Next, the calibration data generating portion 26 outputs a sine wave of the frequency f_{c2} (refer to FIG. 10) outside of the PLL band as a data for calibration. The calibration data outputted by the calibration data generating portion 26, f_{c2} is inputted to the control signal generating portion 30 via the selector 28, and the control signal generating portion 30 generates the control signal Vₘ of VCO 21 to modulate VCO 21. Thereby, VCO 21 outputs an RF modulation signal modulated by the frequency of f_{c2}.

The demodulator 31 demodulates the output signal of VCO 21 and outputs a sine wave having the frequency of f_{c2}. Further, the modulation degree controlling means 32 reads an amplitude value of the sine wave outputted from the demodulator 31 and compares the amplitude value with the held amplitude value of the f_{c1} demodulated to output.

Here, the calibration data generating portion 26 sets the calibration data such that maximum frequency deviations of fc1 and f_{c2} become equal to each other. As described above, a product of a maximum change width of the dividing ratio by the comparison frequency of the reference signal constitutes the maximum frequency deviation of the output signal and therefore, even when the modulation sensitivity with respect to the control voltage Vₜ of VCO 21 is assumedly dispersed, the amplitude of the output of VCO is not dispersed.

On the other hand, with regard to the control signal generated by the control signal generating portion 30 based on the calibration data f_{c2}, the amplitude of the output of VCO depends on the modulation sensitivity Kₘ with respect to the control voltage Vₘ of VCO 21. Therefore, when the modulation sensitivity Kₘ with respect to the control voltage Vₘ of VCO 21 is dispersed, the amplitude is dispersed by an amount of the dispersion. That is, control of the modulation degree is simplified by providing the two control terminals to VCO 21 and using one of the control terminals for the modulation input to VCO.

Therefore, by comparing the output of VCO 21 with the amplitude of the demodulated signal, a difference between gains of modulation (dividing ratio modulation) in the PLL band and modulation (VCO modulation) outside of the PLL band caused by the dispersion in Kₘ can be calculated.

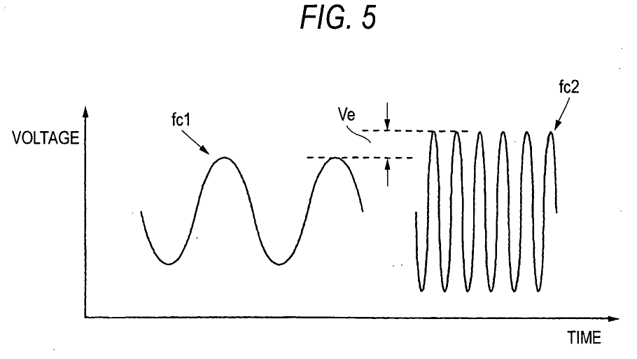

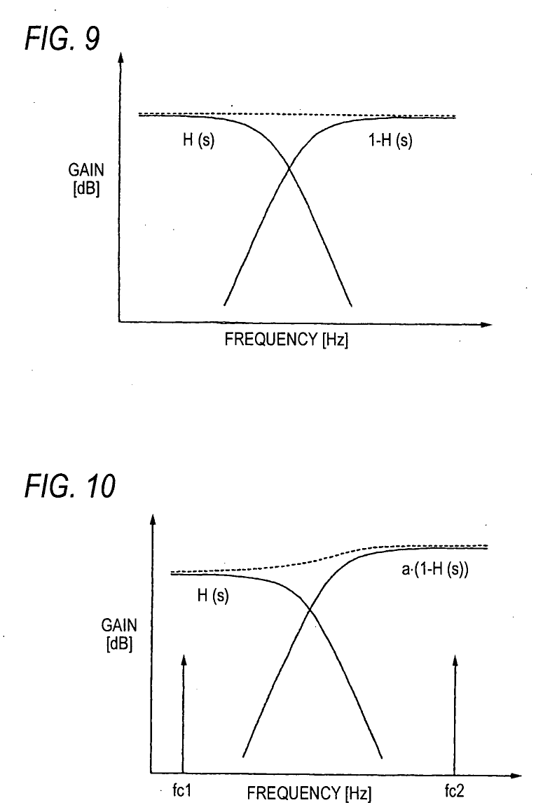

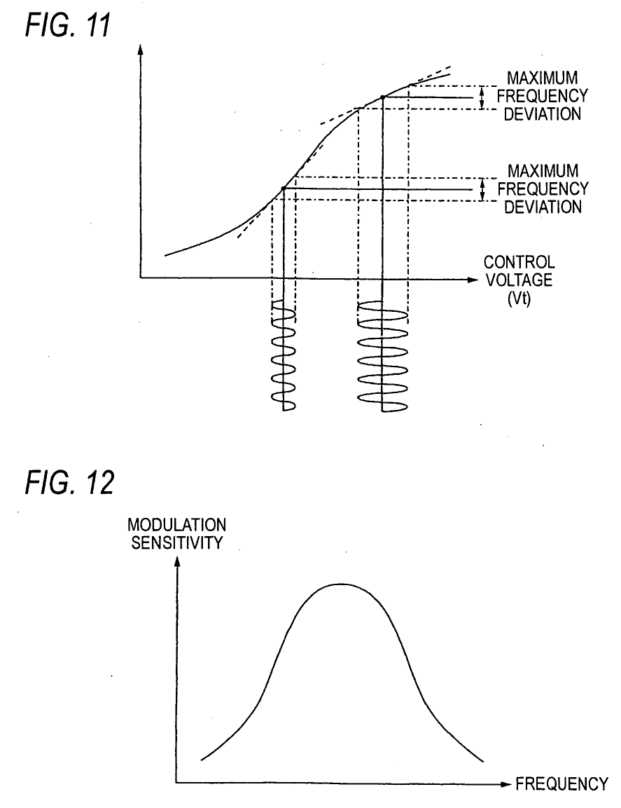

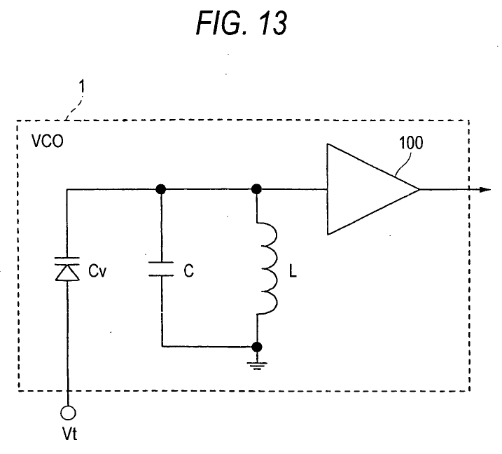

FIG. 5 is a diagram showing an output waveform of the demodulator of the wide band modulation PLL according to the first embodiment. For example, when a value of an element constituting VCO 21 is dispersed, as shown by FIG. 5, the amplitude value of the demodulated output of f_{c2} becomes larger than the amplitude value of the demodulated output of f_{c1}. When a difference of the amplitudes are designated by notation Vₑ, the modulation degree controlling means 32 calculates a modulation degree control signal for controlling the gain of the variable gain amplifier 202 such that the difference Vₑ of the amplitude values becomes null and holds the value. Thereby, the modulation degree with respect to the modulation signal in the PLL band and the modulation degree with respect to the modulation signal outside of the PLL band are aligned and therefore, the frequency characteristic with respect to the modulation signal becomes flat as shown the broken line of FIG. 9.

According to the wide band modulation PLL of the first embodiment of the invention as described above, when the dispersion is brought about in the modulation sensitivity of VCO, only a single data may be held for controlling the modulation degree and therefore, the memory amount can be made to be extremely small and therefore, the wide band modulation PLL which is small-sized and provided with excellent modulation accuracy can be provided at low cost. Further, it is not necessary to execute calibration while changing the frequency of VCO and therefore, the calibration is finished in a short period of time and an increase in fabrication cost by calibration can be reduced. Further, only the difference of the maximum frequency deviations of the demodulated signals of the outputs of VCO may be detected and therefore, the demodulation degree can simply be controlled.

Further, there may be constituted a demodulation degree control system for executing the calibration in a step of fabricating the wide band modulation PLL or a wireless communication apparatus having the wide band modulation PLL by separately providing the demodulator and the modulation degree controlling means, or using a measuring instrument without integrating the demodulator 31 and the modulation degree controlling means 32. In this case, an area on LSI chip is reduced by an amount of the demodulator 31 and the modulation degree controlling means 32 and therefore, low cost formation of LSI is achieved. Further, although the embodiment shows an example of applying frequency modulation in the explanation of the calibration operation, the embodiment is applicable also to phase modulation. Further, the calibration signal is not limited to the sine wave.

Further, as the frequency f_{c1} and f_{c2} of the calibration data, it is preferable to use frequencies by which gains of the wide band modulation PLL with respect to the inputs do not effect an influence on each other. For example, as in f_{c1} and f_{c2} shown in FIG. 10, f_{c1} is a frequency by which a gain of modulation outside of the PLL band is sufficiently reduced and f_{c2} is the frequency by which a gain of modulation in the PLL band is sufficiently reduced.

### Second Embodiment

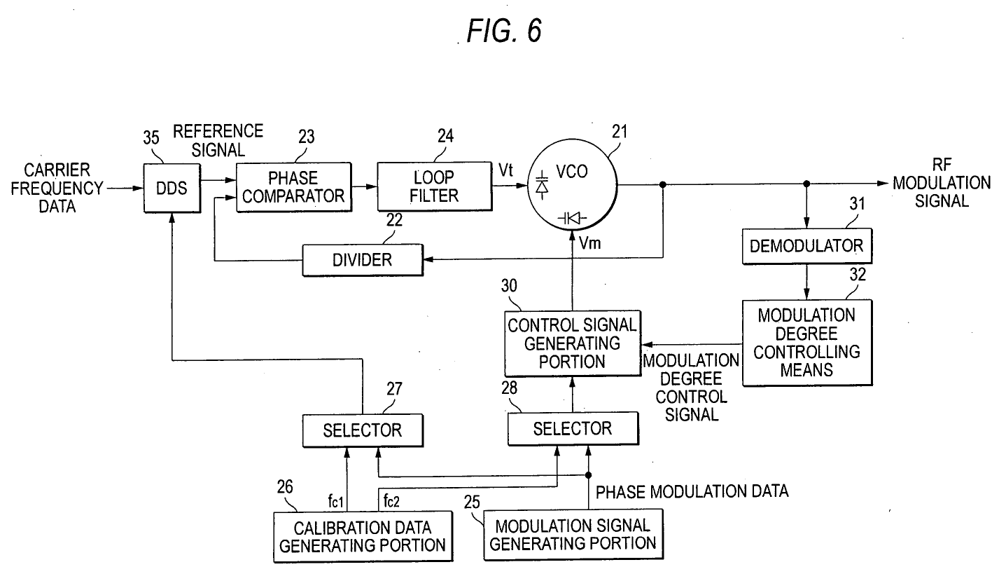

FIG. 6 is an outline constitution diagram showing a wide band modulation PLL for explaining a second embodiment of the invention. Portions duplicated with those of FIG. 1 explained in the first embodiment are attached with the same notations.

In FIG. 6, the wide band modulation PLL according to the second embodiment is provided with a direct digital synthesizer (hereinafter, DDS) 35 and the second embodiment differs from the first embodiment in that portions for executing phase modulation are at two locations of DDS 35 and VCO 21.

DDS 35 directly outputs a result of a numerical value operation via a D/A conversion circuit or the like included therein, and can output the carrier signal and the modulation signal by executing the numeral value calculation based on the carrier frequency data and the phase modulation data as shown by FIG. 6. The modulation by DDS 35 is equivalent to the dividing ratio modulation of the first embodiment and therefore, the calibration can be calculated by a method similar to that of the first embodiment.

Here, the output of DDS 35 can also generate the waveform directly by the numeral value operation, that is, change the frequency and therefore, a fixed divider having a fixed dividing ratio is applicable as the divider 22 used in the wide band modulation PLL. The fixed divider can be constituted by consecutively connecting a plurality of dividers, the later the stage, the lower the operational frequency and therefore, power consumption can be reduced. Particularly, when the dividing ratio is set to the power of 2, the divider may be constituted by successively connecting a plurality of 2 dividers and therefore, power consumption can further be reduced.

Naturally, the divider 2 may be constituted by a variable divider. In this case, it is not necessary to reduce a resolution for changing the frequency by DDS 35 and therefore, the circuit of DDS 35 can be simplified.

According to the wide band modulation PLL of the second embodiment of the invention as described above, when the modulation sensitivity of VCO is dispersed, only a signal data maybe held for controlling the modulation degree and therefore, the memory amount can extremely be reduced and therefore, small-sized formation and low cost formation can be achieved.

Further, it is not necessary to execute the calibration while changing the frequency of VCO and therefore, the calibration can be finished in a short period of time and an increase in fabrication cost can be reduced. Further, only the difference between the maximum frequency deviations of the demodulation signals of the outputs of VCO may be detected and therefore, the modulation degree can simply be controlled.

Further, there may be constituted a modulation degree control system for executing the calibration in a step of fabricating the wide band modulation PLL or a wireless communication apparatus having the wide band modulation PLL by separately providing the demodulator and the modulation degree controlling means, or using a measuring instrument or the like without integrating the demodulator 31 and the modulation degree controlling means 32. In this case, an area on an LSI chip can be reduced by an amount of the demodulator 31 and the modulation degree controlling means 32 and therefore, low cost formation of LSI can be achieved.

### Third Embodiment

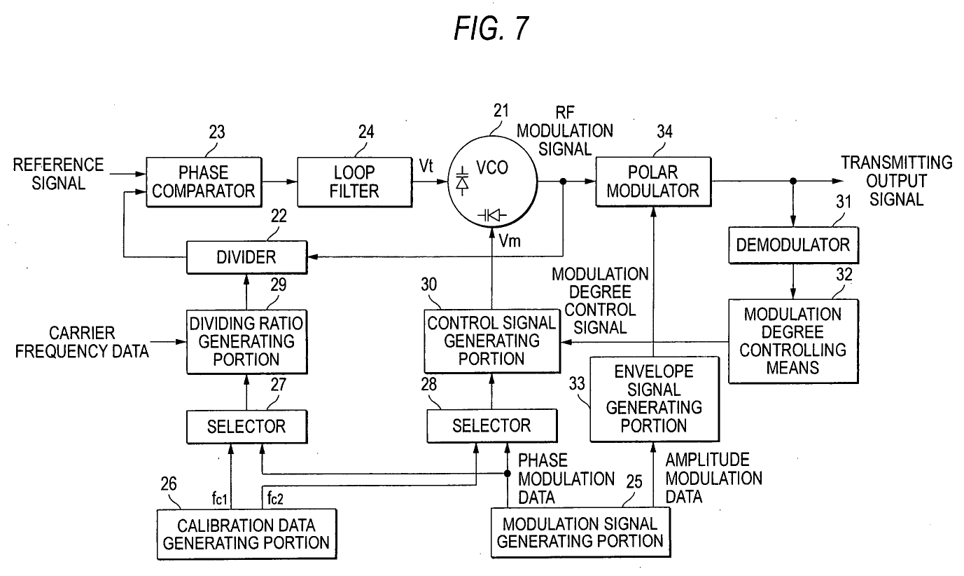

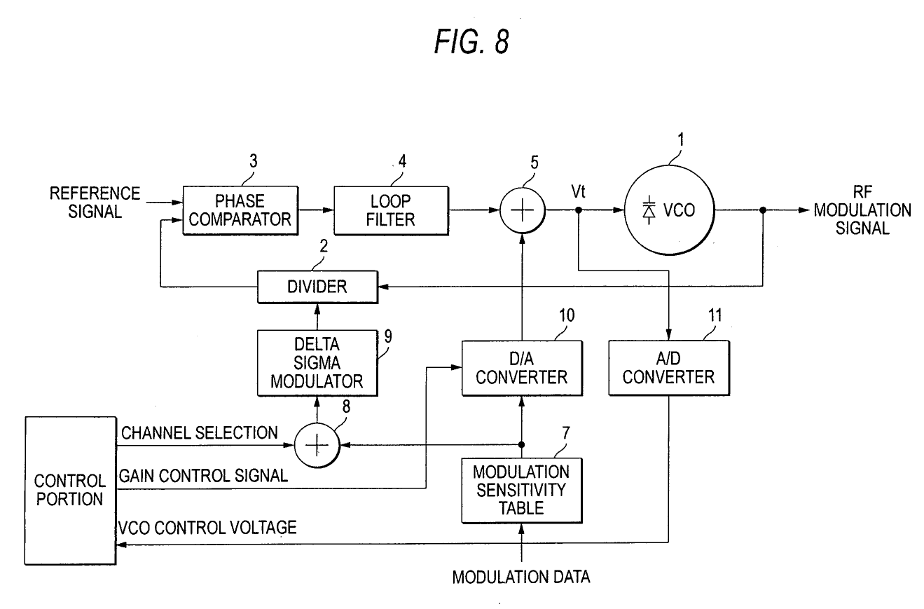

FIG. 7 is an outline constitution diagram showing a polar modulation system for explaining a third embodiment of the invention. Portions duplicated with those of FIG. 1 explained in the first embodiment are attached with the same notations. As shown by FIG. 7, the polar modulation system according to the third embodiment is further provided with an envelope signal generating portion 33 and a polar modulator 34 in addition to the wide band modulation PLL explained in the first embodiment.

Here, as in, for example, HPSK (Hybrid Phase Shift Keying), the modulation signal generating portion 25 generates a modulation signal modulating a phase as well as an envelop, separates the modulation signal into phase modulation data and amplitude modulation data and outputs the respectives thereof. The envelop signal generating portion 33 converts a digital amplitude modulation data into an analog envelope signal. The polar modulator 34 synthesizes the RF modulation signal outputted by VCO 21 and the envelope signal outputted by the envelope signal generating portion 33 on the polar coordinates plane and generates and outputs a transmitting output signal.

Further, although the calibration operation is similar to that of Embodiment 1, the demodulator 31 demodulates the transmitting output signal outputted by the polar modulator 34 and the modulation degree control signal is set by the modulation degree controlling means 32.

According to the polar modulation system of the third embodiment of the invention described above, the modulation degree control signal is generated by demodulating the output of the polar modulator and therefore, a distortion of a phase generated at the polar modulator can also be calibrated.

Further, only a single data may be held for controlling the modulation degree and therefore, the memory amount is extremely small and low cost formation can be achieved.

Further, it is not necessary to execute calibration while changing the frequency of VCO and therefore, the calibration is finished in a short period of time and an increase in fabrication cost is small. Further, only the difference between the maximum frequency deviations of the demodulated signals of the outputs of the polar modulator may be detected and therefore, the modulation degree can simply be controlled.

Further, there may be constituted a modulation degree control system executing the calibration in a step of fabricating the wide band modulation PLL or a wireless communication apparatus having the wide band modulation PLL by separately providing the demodulator and the modulation degree controlling means or using a measuring instrument or the like without integrating the demodulator 31 and the modulation degree controlling means 32. In this case, an area on an LSI chip can be reduced by an amount of the modulator 31 and the modulation degree controlling means 32 and therefore, low cost formation of LSI is achieved. Further, the wide band modulation PLL shown in FIG. 6 explained in the second embodiment may be applied to the polar modulation system.

Although an explanation has been given of the invention in details and in-reference to the specific embodiments, it is apparent for the skilled person that the invention can variously be changed or modified without deviating from the spirit and the range of the invention.

The application is based on Japanese Patent Publication No. 2003-298857 filed on Aug. 22, 2003 and a content thereof is incorporated herein by reference.

### INDUSTRIAL APPLICABILITY

The wide band modulation PLL of the invention achieves an effect of capable of promoting the modulation accuracy by small-sized formation and at low cost and is useful for a wireless communication apparatus or the like of a mobile wireless machine, wireless base station apparatus or the like.

1. A wide band modulation PLL comprising:
a PLL portion including a voltage control oscillator, a divider for dividing an output signal of the voltage control oscillator, a phase comparator connected to a post stage of the divider, and a loop filter for averaging an output of the phase comparator;
a first modulation input portion for inputting a first modulation signal to the voltage control oscillator to modulate based on an inputted modulation data; and
a second modulation input portion for inputting a second modulation signal to a position of the PLL portion different from the voltage control oscillator based on the modulation data;
wherein the voltage control oscillator includes a first control terminal inputted with the first modulation signal and a second control terminal inputted with a signal based on the second modulation signal;
wherein the first modulation input portion and the second modulation input portion are respectively inputted with a first calibration data and a second calibration data in controlling a modulation degree; and
wherein the modulation degree of the first modulation input portion is controlled by comparing signals based on outputs from the voltage control oscillator when the first calibration data and the second calibration data are inputted.

2. The wide band modulation PLL according to claim 1;
wherein the first calibration data is a sine wave signal outside of a PLL band and the second calibration data is a sine wave signal in the PLL band.

3. The wide band modulation PLL according to claim 1;
wherein maximum frequency deviations of the first calibration data and the second calibration data are equal to each other.

4. The wide band modulation PLL according to claim 3;
wherein the modulation degree of the first modulation input portion is controlled based on a difference between the maximum frequency deviations of the signals based on outputs of the voltage control oscillator when the first calibration data is inputted and when the second calibration data is inputted.

5. The wide band modulation PLL according to claim 1;
wherein the second modulation portion includes dividing ratio generating means for controlling a dividing ratio of the divider based on a carrier frequency data and the modulation data.

6. The wide band modulation PLL according to claim 1;
wherein the second modulation portion includes a direct digital synthesizer for generating a modulation signal based on a carrier frequency data and the modulation data to output to the phase comparator.

7. The wide band modulation PLL according to claim 6;
wherein the divider includes a plurality of dividers having fixed dividing ratios which are consecutively connected.

8. A wireless terminal apparatus comprising the wide band modulation PLL according to claim 1.

9. A modulation degree control system of a wide band modulation PLL comprising:
the wide band modulation PLL according to any one claim 1;
a demodulator for demodulating an output of the voltage control oscillator of the wide band modulation PLL; and
modulation degree controlling means for outputting a modulation degree control signal to the first modulation input portion of the wide band modulation PLL by controlling a modulation degree based on an output of the demodulator.

10. A polar modulation system comprising:
the wide band modulation PLL according to claim 1;
an envelope signal generating portion for generating an envelope signal based on an inputted amplitude modulation data; and
a polar demodulator for generating a transmitting output signal based on an output of the voltage control oscillator of the wide band modulation PLL and an output signal of the envelope signal generating portion.

11. A modulation degree control system of a polar modulation system comprising:
the polar modulation system according to claim 10;
a demodulator for demodulating an output of the voltage control oscillator of the wide band modulation PLL; and
modulation degree controlling means for outputting a modulation degree control signal to the first modulation input portion of the wide band modulation PLL by controlling a modulation degree based on an output of the demodulator.

12. A method of adjusting a modulation degree of a wide band PLL which is a method of controlling a modulation degree of a wide band modulation PLL comprising a PLL portion including a voltage control oscillator, a divider for dividing an output signal of the voltage control oscillator, a phase comparator connected to a post stage of the divider, and a loop filter for averaging an output of the phase comparator, said method comprising:
a step of inputting a first calibration data to a first control terminal of the voltage control oscillator;
a step of inputting a second calibration data to a position of the PLL portion different from the voltage control oscillator;
a step of demodulating an output of the voltage control oscillator when the first calibration data is inputted;
a step of demodulating the output of the voltage control oscillator when the second calibration data is inputted; and
a step of controlling a modulation degree of a modulation signal inputted to the first control terminal of the voltage control oscillator based on the demodulated signal.

13. A method of controlling a modulation degree of a wide band modulation PLL which is a method of controlling a modulation degree of a polar modulation system comprising a wide band modulation PLL including a voltage control oscillator, a divider for dividing an output signal of the voltage control oscillator, a phase comparator connected to a post stage of the divider, and a loop filter for averaging an output of the phase comparator, said method comprising:
a step of inputting a first modulation signal based on a first calibration data to a first control terminal of the voltage control oscillator;
a step of inputting a second modulation signal based on a second calibration data to a position of the PLL portion different from the voltage control oscillator;
a step of synthesizing an output signal of the voltage control oscillator of the PLL portion based on an amplitude modulation data at a polar modulator;
a step of demodulating an output of the polar modulator when the first calibration data is inputted;
a step of demodulating the output of the polar modulator when the second calibration data is inputted; and
a step of controlling a modulation degree of a modulation signal inputted to the first control terminal of the voltage control oscillator based on the demodulated signal.

14. (canceled)
